(19) United States
(12) Patent Application Publication
(10) Pub. No.: US 2010/0090256 A1
(43) Pub. Date: Apr. 15, 2010

(54) SEMICONDUCTOR STRUCTURE WITH STRESS REGIONS

(76) Inventors: Hung-Wei Chen, Chu-Pei City (TW); Yider Wu, Chu-Pei City (TW)

Correspondence Address: SCHMEISER, OLSEN & WATTS, 22 CENTURY HILL DRIVE, SUITE 302, LATHAM, NY, 12110, US

(21) Appl. No.: 12/249,152

(22) Filed: Oct. 10, 2008

(51) Int. Cl. H01L 29/04

(52) U.S. Cl. 257/255; 257/E29.004

(57) ABSTRACT

A semiconductor structure with stress regions includes a substrate defining a first and a second device zone; a first and a second stress region formed in each of the first and second device zones to yield stress different in level; and a barrier plug separating the two device zones from each other. Due to the stress yielded at the stress regions, increased carrier mobility and accordingly, increased reading current can be obtained, and a relatively lower reading voltage is needed to obtain initially required reading current. As a result, the probability of stress-induced leakage current (SILC) is reduced and the semiconductor memory structure may have enhanced data retention ability.

### FIELD OF THE INVENTION

The present invention relates to a metal-oxide-semiconductor (MOS) structure, and more particularly, to a semiconductor structure with stress regions.

### BACKGROUND OF THE INVENTION

Following the advancement in scientific technologies, the process technique for flash memory has also moved into the nano era. To enable increased device operating speed, high integration density of device, reduced device operating voltage, etc., it has become an inevitable trend to minimize the gate channel length and the oxide layer thickness of the semiconductor device. The measure of gate line width has been reduced from the past micrometer (10⁻⁶ meter) to the current nanometer (10⁻⁹ meter). However, the device size reduction also brings many problems, such as stress-induced leakage current (SILC) and worsened short channel effect due to reduced gate line width. To avoid the device from being adversely affected by the short channel effect, the oxide layer thereof must have a thickness as small as possible. However, when the oxide layer has a thickness of 8 nm or below, the physical limit of material thereof would become a barrier in the manufacturing process of the device. By SILC, it means an increased leakage current at the gate of a device after a constant voltage stress or a constant current stress is applied to the device. When the oxide layer is reduced in its thickness, the SILC becomes a very important issue. Increase of SILC would lead to loss of electrons retained in the floating gate and accordingly, largely lowered data retention ability and increased power consumption of the metal-oxide-semiconductor (MOS) device. Further, the gate disturb and drain disturb in memory cells also largely restrict the thickness of the oxide layer during the course of device size reduction. Therefore, when the device size has reached its physical limit, it becomes a very urgent need to find a way other than the device size reduction to overcome the shortcomings.

To improve the current performance in the device, there are many ways for increasing the carrier mobility. One of these ways is the already known strained Si channel approach, in which stressed Si channel is formed. The stress is helpful in increasing electron or hole mobility, so that the characteristics of MOS device may be improved by the stressed channel. The application of stress is also beneficiary to the reduction of gate disturb and drain disturb in memory cells. That is, a relatively higher drain current may be obtained while a relatively lower drain voltage is used. Therefore, only a lowered drain voltage is needed to achieve the initially required drain current to thereby enable the gate and drain disturb to be reduced.

The increase of stress maybe achieved by forming a stressed layer on the MOS device. A contact etch stop layer (CESL) may serve as the stressed layer. In depositing the stressed layer, a in-planar stress is yielded to result in energy band separation. Please refer to FIG. 7 that describes the relation between the stress direction and the energy band in a semiconductor memory. That is, there is a rising energy band at the fourfold degenerate (Δ4) energy valley corresponding to the kₓ and k_{y} directions in the space k, and a lowering energy band at the twofold degenerate (Δ2) energy valley corresponding to the k_{z} direction in the space k. Therefore, most of the electrons are distributed in the Δ2 energy valley having lower energy band (i.e., having lower effective mass). In addition, a strain-induced band splitting, in the one point of view, reduces the inter-valley scattering rate (or optical phonon scattering rate), and, in the other point of view, reduces the effective density of state in the conduction band to thereby reduce the intra-valley scattering rate (or acoustic phonon scattering rate). Therefore, the lowered effective mass and scattering rate is helpful in improving the electron mobility. Similarly, the separated energy-degenerate of light-hole band and heavy-hole band in the valence band, and as well as the lowered inter-band and the intra-band scattering rate also enable the hole mobility to be improved. However, an overly thick stressed layer would lead to difficulty in subsequent gap filling, while an overly thin stressed layer would lead to limited the stress effect.

It is therefore very important to enhance device characteristics through improvement in the stressed layer and other arrangements related thereto without adding complexity to device design.

### SUMMARY OF THE INVENTION

A primary object of the present invention is to provide a semiconductor structure with stress regions to improve the carrier mobility.

To achieve the above and other objects, the semiconductor structure with stress regions according to the present invention includes a substrate defining a first device zone and a second device zone thereon, each of the first device zone and the second device zone including a gate with a drain being formed between the first and the second device zone, and a salicide layer being formed on a top of each of the gates, but not on the drain; a first and a second stress region being formed in each of the first and the second device zone, and the stress yielded at the first stress regions and at the second stress regions being different in level, and each of the first stress regions including a pair of L-shaped spacers facing away from each other; and a barrier plug being formed between the first and the second device zone to separate the two device zones from each other.

In an embodiment of the present invention, each of the first stress regions includes a pair of L-shaped spacers facing away from each other, and each of the second stress regions is a contact etch stop layer (CESL). The stress yielded at the second stress regions is larger than that yielded at the first stress regions, and the yielded stress is uniaxial tensile stress.

In an embodiment of the present invention, the substrate is a silicon substrate with an n-channel formed along a direction <110>.

In another embodiment of the present invention, the substrate a silicon substrate with a channel formed along a direction <100>.

With the above arrangements, the semiconductor structure with stress regions according to the present invention is able to yield an appropriate stress and accordingly has enhanced the carrier mobility.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIGS. 1 through 6 are sectional views showing a wafer in different process steps for forming a semiconductor structure of the present invention; and

FIG. 7 describes the relation between stress direction and energy band in a MOS semiconductor.

### DETAILED DESCRIPTION OF THE PREFERRED EMBODIMENTS

A semiconductor structure with stress regions according to an embodiment of the present invention will now be described with reference to the accompanying drawings. For the purpose of clarity and easy to understand, elements that are the same in the drawings and the illustrated embodiments are denoted by the same reference numeral.

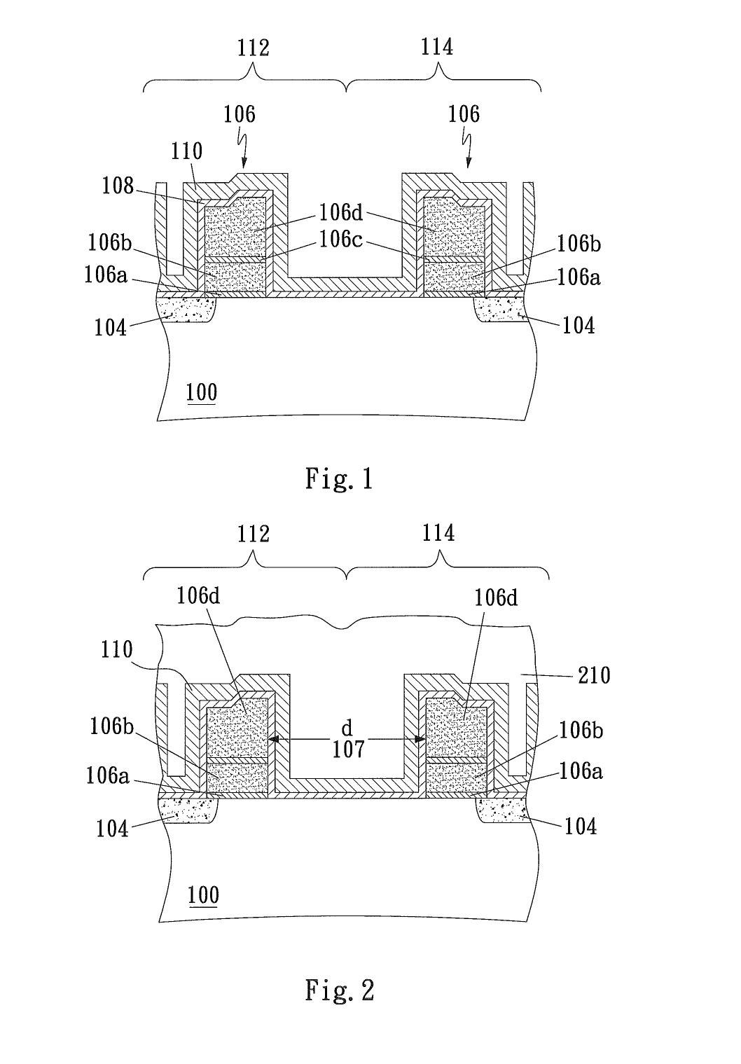

Please refer to FIG. 1 that is a sectional view of a wafer for forming the present invention. As shown, the wafer includes a semiconductor substrate 100, on which a first device zone 112 and a second device zone 114 are defined. The first and the second device zone 112, 114 may be N-channel devices, P-channel devices, or a combination thereof. In the illustrated embodiment of the present invention, the first and second device zones 112, 114 are both N-channel devices. In each of the first and the second device zone 112, 114 on the semiconductor substrate 100, there are formed a source 104, a gate 106, a tunneling oxide layer 106a, a floating gate 106b, a dielectric layer 106c, a control gate 106d, a first oxide layer 108, and a second oxide layer 110. The material for the substrate 100 may be silicon, silicon-germanium (SiGe), silicon on insulator (SOI), silicon germanium on insulator (SGOI), or germanium on insulator (GOI). In the illustrated embodiment of the present invention, the substrate 100 is a silicon substrate having a crystal orientation (100) and a channel formed along a direction <110>. The second oxide layer 110 may be silicon nitride (SiN), silicon oxynitride (SiON), silicon oxide, etc. In the illustrated embodiment of the present invention, the second oxide layer 110 is SiN.

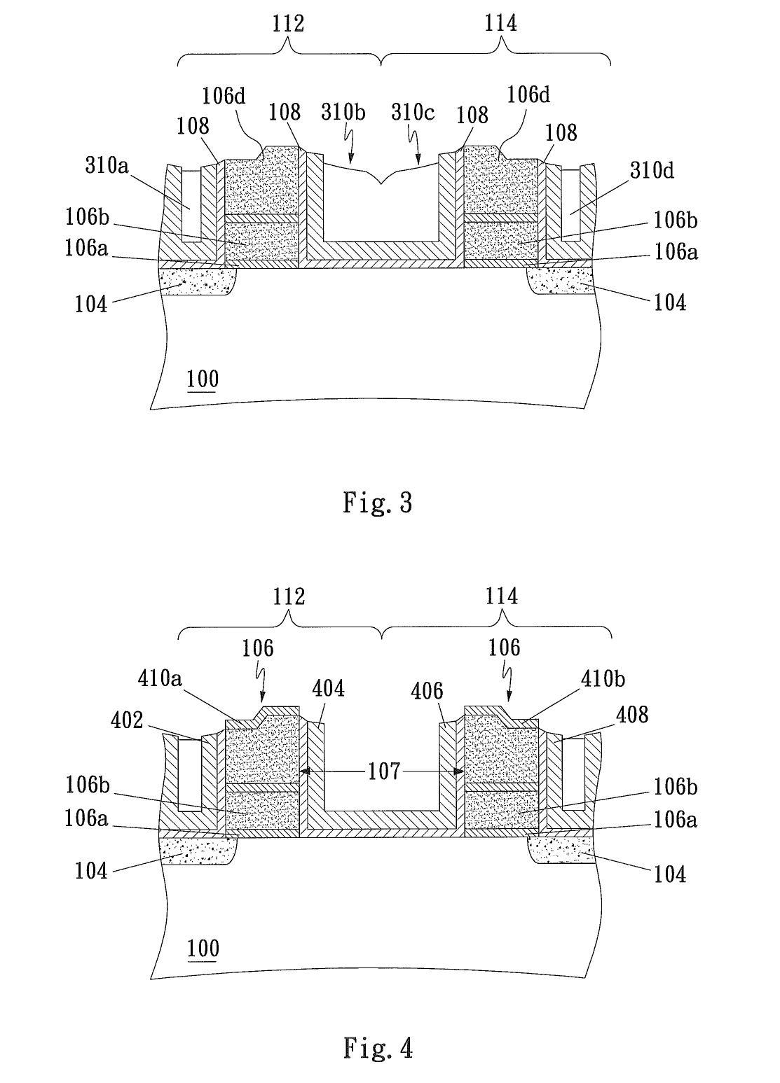

Please refer to FIG. 2. An oxide layer 210 is deposited on the substrate 100 through a known deposition technique, such as the chemical vapor deposition (CVD) process with ammonia (NH₃) and silicon hydride (SiH₄) used as source gas, the rapid thermal chemical vapor deposition (RTCVD) process, or the atomic layer deposition (ALD) process. The oxide layer 210 has a thickness between 200 Å and 1500 Å. In the illustrated embodiment of the present invention, the thickness of the oxide layer 210 is 750 Å. The second oxide layer 110 and the oxide layer 210 at lateral sides of the floating gates 106b and the control gates 106d have a total deposition thickness at least larger than one half of the width d of an area 107 between the first and the second device zone 112, 114, so as to seal the area 107. Then, the oxide layer 210 is etched to form a plurality of oxide spacers 310a, 310b, 310c, and 310d, as shown in FIG. 3. And, the oxide layers 110, 210 atop the control gates 106d are completely removed through etching, as shown in FIG. 3.

Please refer to FIG. 4. After the second oxide layers 110 atop the control gates 106d are etched away, the remained portions of the second oxide layers 110 form a first, a second, a third, and a fourth L-shaped spacer 402, 404, 406, and 408. Wherein, the first and the third spacer 402, 406 are formed as the reversed L shape. These spacers are paired, so that each pair of spacers includes an L-shaped spacer and a sideward reverse L-shaped spacer facing away from each other. More specifically, the first and second L-shaped spacers 402, 404 form a pair, and the third and fourth L-shaped spacers 406, 408 form another pair. Wherein, the second and the third L-shaped spacer 404, 406 are connected to each other to form a U shape. The L-shaped spacer pairs 402, 404 and 406, 408 form a first stress region in the first and second device zones 112, 114 to yield required uniaxial tensile stress for the semiconductor structure of the present invention. This uniaxial tensile stress may be adjusted through proper material selection and the forming process. In the forming process, there are some adjustable process parameters, including temperature, deposition speed, power, etc. One of ordinary skill in the art can easily find the relation between these process parameters with deposition layer stress.

Then, the oxide layer 310b, 310c remained in the area 107 is completely removed through dry etching or wet etching process. Thereafter, a metal silicide layer consisting of cobalt (Co), titanium (Ti), nickel (Ni), or molybdenum (Mo) is formed on the substrate 100, and a rapid thermal treatment process is conducted, so that a salicide layer 410a, 410b is formed on a top surface of each of the gates 106 to reduce parasitic resistance and increase device driving force.

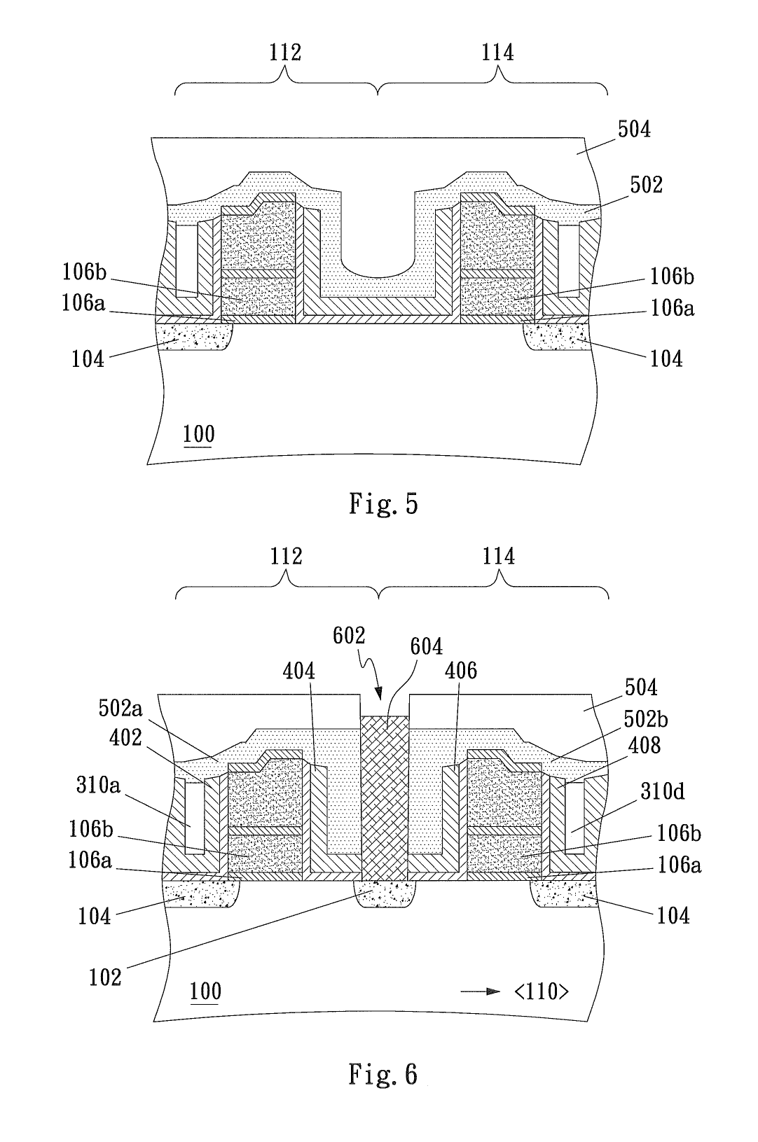

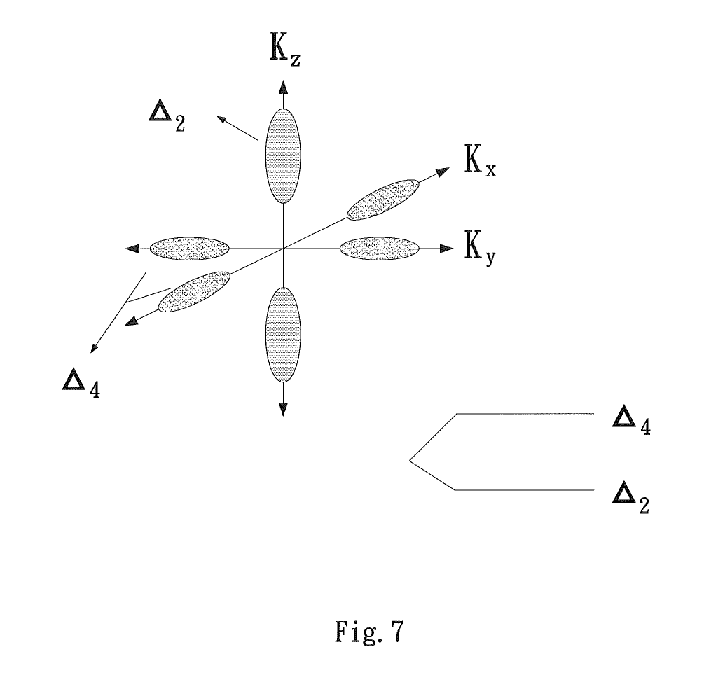

Please refer to FIG. 5. Thereafter, a contact etch stop layer (CESL) 502 is deposited on the semiconductor substrate 100. The CESL 502 may be SiN, silicon oxynitride, or silicon oxide. In the illustrated embodiment of the present invention, the CESL 502 is SiN. The CESL 502 may have a deposition thickness between 100 Å to 1500 Å. In the illustrated embodiment, through the deposition process, the CESL 502 forms a second stress region in the present invention to yield required uniaxial tensile stress for the semiconductor structure of the present invention. Wherein, the increment of stress is in relation to the number of hydrogen atoms which are contained in the CESL 502. The lower the contained number of hydrogen atoms is, the higher the stress increment is. In the illustrated embodiment, the uniaxial tensile stress yielded at the L-shaped spacers 402, 404, 406, 408 is smaller than that yielded at the CESL 502. Thereafter, an inter-layer dielectric (ILD) 504, such as SiO₂, is deposited on the CESL 502.

Please refer to FIG. 6. Then, through a known photoresist and mask process, a contact 602 is formed by anisotropic etching from the inter-layer dielectric 504 into the CESL 502. Then, the ion implantation at the drain for forming a drain 102 and the rapid thermal treatment for activating device doping are conducted. Further, a barrier plug 604 is deposited in the contact 602 using CVD process to direct contact with the drain 102, so that the two connected second and third L-shaped spacers 404, 406 are separated from one another and the CESL 502 is split into two parts 502a and 502b.

In the above-described embodiment, there are formed two stress regions, namely, a first stress region consisting of the L-shaped spacer pair 402, 404/406, 408, and a second stress region consisting of the split contact etch stop layer 502a/502b in each of the first and the second device zone 112, 114. Wherein, all the L-shaped spacers 402, 404, 406, 408 and the contact etch stop layers 502a, 502b are subjected to rapid thermal treatment in different process steps to yield appropriate uniaxial tensile stress, so as to increase effective mass of electrons and thereby reduce tunneling leakage current. As a result, it is possible to decrease the thickness of tunneling oxide layers 106a and reduce the occurrence of short channel effect (SCE) while the stress-induced leakage current (SILC) is unchanged.

In the illustrated embodiment of the present invention, the uniaxial tensile stress yielded at the L-shaped spacers 402, 404, 406, 408 is smaller than that yielded at the CESL 502a, 502b. Moreover, since the substrate 100 has a crystal orientation (100) and a channel formed along direction <110>, these features together with the uniaxial tensile stress yielded at the stress regions make the memory device produced from the semiconductor structure of the present invention having increased electron mobility, and it is helpful in obtaining an increased reading current. That is, it is possible to achieve an initially desired reading current with only a lowered reading voltage to thereby have upgraded data retention ability.

In another embodiment of the present invention, the substrate 100 has a crystal orientation (100) and a channel formed along direction <100>. To compare with the substrate 100 having a channel formed along direction <110>, electrons in the channel formed along direction <100> have a relatively higher piezoresistance coefficient. Therefore, the uniaxial tensile stress yielded at the stress regions formed in this embodiment is able to further increase the electron mobility in the memory device. In addition, due to the lattice direction <100>, the hole mobility in the p-channel metal-oxide-semiconductor field-effect transistor (PMOS) would not be reduced.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A semiconductor flash memory structure with stress regions, comprising:
a substrate defining a first device zone and a second device zone thereon; each of the first device zone and the second device zone including a gate with a drain being formed between the first and the second device zone, said gate divided into a floating gate and a control gate by a dielectric layer; and a salicide layer being formed on a top of each of the gates, but not on the drain;
a first and a second stress region being formed in each of the first and the second device zone, and the stress yielded at the first stress regions and at the second stress regions being different in level, and the first stress regions in each of the first and second device zone including a pair of L-shaped spacers facing away from each other; and
a barrier plug being formed between the first and the second device zone to separate the two device zones from each other; and
wherein the stress yielded at the first stress regions is smaller than the stress yielded at the second stress regions.

2. The semiconductor flash memory structure with stress regions as claimed in claim 1, wherein the substrate is a silicon substrate with a channel formed along a direction <110>.

3. The semiconductor flash memory structure with stress regions as claimed in claim 2, wherein the channel is an n-channel.

4. The semiconductor flash memory structure with stress regions as claimed in claim 1, wherein the substrate is a silicon substrate with a channel formed along a direction <100>.

5. The semiconductor flash memory structure with stress regions as claimed in claim 1, wherein the L-shaped spacers are selected from the group consisting of SiN, silicon oxynitride, and silicon oxide.

6. The semiconductor flash memory structure with stress regions as claimed in claim 1, wherein the second stress region in each of the first and second device zone is a contact etch stop layer (CESL).

7. The semiconductor flash memory structure with stress regions as claimed in claim 6, wherein the contact etch stop layer is selected from the group consisting of SiN, silicon oxynitride, and silicon oxide.

8. (canceled)

9. The semiconductor flash memory structure with stress regions as claimed in claim 1, wherein the yielded stress is a uniaxial tensile stress.
